(19) United States
(12) Patent Application Publication
(10) Pub. No.: US 2023/0058749 A1
(43) Pub. Date: Feb. 23, 2023

(54) ADAPTIVE MATRIX MULTIPLIERS

(71) Applicant: XILINX, INC., San Jose, CA (US)

(72) Inventors: Stephan MUNZ, Dublin (IE); Francisco Barat QUESADA, Dublin (IE); Baris OZGUL, Dublin (IE); Javier CABEZAS RODRIGUEZ, Austin, TX (US); Zachary DICKMAN, Dublin (IE); Pedro Miguel Parola DUARTE, Skerries (IE); Dylan STUART, Maynooth (IE); Juan J. NOGUERA SERRA, San Jose, CA (US)

(21) Appl. No.: 17/867,625

(22) Filed: Jul. 18, 2022

Related U.S. Application Data
(60) Provisional application No. 63/235,314, filed on Aug. 20, 2021.

(51) Int. Cl. G06F 17/16; G06F 15/80; H03K 19/173

(52) U.S. Cl. CPC G06F 17/16; G06F 15/8046; H03K 19/1737

(57) ABSTRACT

Examples herein describe techniques for adapting a multiplier array (e.g., a systolic array implemented in a processing core) to perform different dot products. The processing core can include data selection logic that enables different configurations of the multiplier array in the core. For example, the data selection logic can enable different configurations of the multiplier array while using the same underlying hardware. That is, the multiplier array is fixed hardware but the data selection can transmit data into the matrix multiplier such that it is configured to perform different length dot products, perform more dot products in parallel, or change its output precision. In this manner, the same underlying hardware (i.e., the multiplier array) can be reconfigured for different dot products which can result in much more efficient use of the hardware.

### CROSS REFERENCE TO RELATED APPLICATION

This application claims priority to the U.S. Provisional Application No. 63/235,314, filed on Aug. 20, 2021 of which is incorporated herein in by reference in its entirety.

### TECHNICAL FIELD

Examples of the present disclosure generally relate to adaptive matrix multipliers, and more specifically, to handling different dot products used adaptive matrix multipliers.

### BACKGROUND

Matrix multiplication is made up of a series of dot products. Many different software applications require the hardware to perform a dot product or a matrix multiplication such as machine learning applications, radio frequency (RF) applications, simulators, and the like. As such, matrix multiplication (and the underlying dot products) is a common task for many hardware systems. Many hardware systems have specialized circuitry (e.g., matrix multipliers or systolic arrays) for performing matrix multiplications. However, as is typical in hardware, this specialized circuitry is inflexible. The hardware typically performs a fixed dot product, regardless of the size of the input or the desired output precision.

### SUMMARY

Techniques for operating an adaptive multiplier array are described. One example is an integrated circuit (IC) that includes a data processing engine which in turn includes a data selection circuit configured to receive data and an adaptive multiplier array connected to the data selection circuit. The data selection circuit is configured to enable different configurations of the adaptive multiplier array. Further, each of the different configurations results in the adaptive multiplier array performing a different dot product on the received data.

One example described herein is an IC that includes a data selection circuit configured to receive data and an adaptive multiplier array connected to the data selection circuit. The data selection circuit is configured to enable different configurations of the adaptive multiplier array. Further, each of the different configurations results in the adaptive multiplier array performing a different dot product on the received data.

One example described herein is a method that includes receiving, at a data processing engine, a first instruction to execute a first dot product, configuring a data selection circuit in the data processing engine to enable a first configuration of an adaptive multiplier array corresponding to the first dot product, receiving, at the data processing engine, a second instruction to execute a second dot product, and configuring the data selection circuit in the data processing engine to enable a second configuration of the adaptive multiplier array corresponding to the second dot product.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a block diagram of a SoC that includes a data processing engine array, according to an example.

FIG. 2 is a block diagram of a data processing engine in the data processing engine array, according to an example.

FIG. 3 illustrates a multi-layer neural network, according to an example.

FIG. 4 illustrates a systolic array for performing dot products for a neural network, according to an example.

FIG. 5 is a block diagram of core containing an adaptive multiplier array, according to an example.

FIG. 6 is a flowchart for reconfiguring an adaptive multiplier array, according to an example.

FIG. 7 is a chart illustrate different multiplier array configurations, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Examples herein describe techniques for adapting a multiplier array (e.g., a systolic array or matrix multiplier implemented in a processing core) to perform different dot products. Typical cores in a processors, or more generally, data processing engines contain multiplier arrays that perform dot products. Because these multiplier arrays are fixed in hardened circuitry, they cannot be adapted to efficiently execute different matrix multiplications (or the dot products associated therewith). For example, machine learning applications can include several if not hundreds of layers where many of those layers may request the core to perform different dot products of different lengths or sizes. For example, a multiplier array (e.g., a matrix multiplier) in the core may be designed to perform an 8 bit×8 bit dot product with a set output precision, but one layer may request that the core perform a 4 bit×4 bit dot product while another layer requests that the core perform a 8 bit×8 bit dot product but on more channels and with a lower output precision. In any case, the multiplier array may be used inefficiently.

In the embodiments herein, the processing core includes data selection logic that can enable different configurations of the multiplier array in the core. For example, the data selection logic can enable different configurations of the multiplier array while using the same underlying hardware. That is, the multiplier array is fixed hardware but the data selection circuit can transmit data to the multiplier array such that it performs different length dot products, performs more dot products in parallel, or changes its output precision. In this manner, the same underlying hardware (i.e., the multiplier array) can be reconfigured for different dot products which can result in much more efficient use of the hardware.

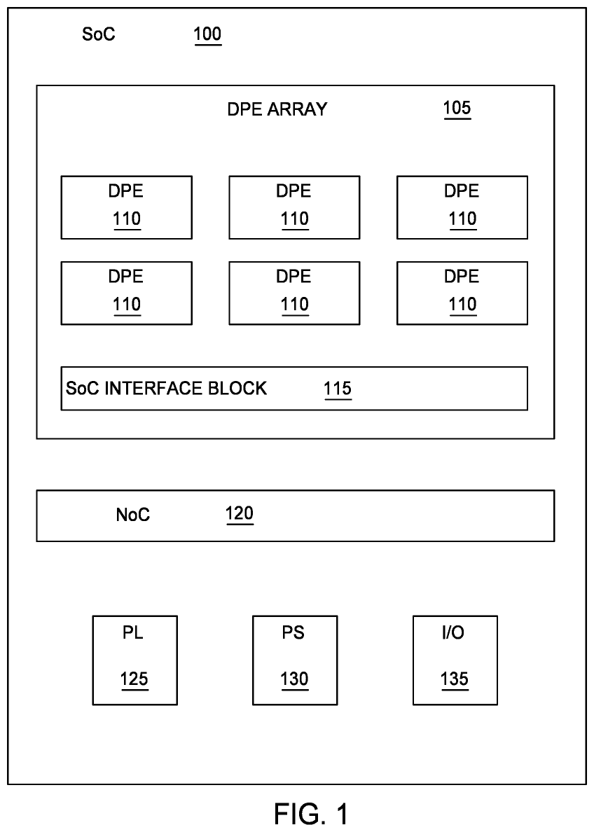

FIG. 1 is a block diagram of a SoC 100 that includes a data processing engine (DPE) array 105, according to an example. The DPE array 105 includes a plurality of DPEs 110 which may be arranged in a grid, duster, or checkerboard pattern in the SoC 100. Although FIG. 1 illustrates arranging the DPEs 110 in a 2D array with rows and columns, the embodiments are not limited to this arrangement. Further, the array 105 can be any size and have any number of rows and columns formed by the DPEs 110.

In one embodiment, the DPEs 110 are identical. That is, each of the DPEs 110 (also referred to as tiles or blocks) may have the same hardware components or circuitry. Further, the embodiments herein are not limited to DPEs 110. Instead, the SoC 100 can include an array of any kind of processing elements, for example, the DPEs 110 could be digital signal processing engines, cryptographic engines, Forward Error Correction (FEC) engines, or other specialized hardware for performing one or more specialized tasks.

In FIG. 1, the array 105 includes DPEs 110 that are all the same type (e.g., a homogeneous array). However, in another embodiment, the array 105 may include different types of engines. For example, the array 105 may include digital signal processing engines, cryptographic engines, graphic processing engines, and the like. Regardless if the array 105 is homogenous or heterogeneous, the DPEs 110 can include direct connections between DPEs 110 which permit the DPEs 110 to transfer data directly as described in more detail below.

In one embodiment, the DPEs 110 are formed from software-configurable hardened logic—i.e., are hardened. One advantage of doing so is that the DPEs 110 may take up less space in the SoC 100 relative to using programmable logic to form the hardware elements in the DPEs 110. That is, using hardened logic circuitry to form the hardware elements in the DPE 110 such as program memories, an instruction fetch/decode unit, fixed-point vector units, floating-point vector units, arithmetic logic units (ALUs), multiply accumulators (MAC), and the like can significantly reduce the footprint of the array 105 in the SoC 100. Although the DPEs 110 may be hardened, this does not mean the DPEs 110 are not programmable. That is, the DPEs 110 can be configured when the SoC 100 is powered on or rebooted to perform different functions or tasks.

The DPE array 105 also includes a SoC interface block 115 (also referred to as a shim) that serves as a communication interface between the DPEs 110 and other hardware components in the SoC 100. In this example, the SoC 100 includes a network on chip (NoC) 120 that is communicatively coupled to the SoC interface block 115. Although not shown, the NoC 120 may extend throughout the SoC 100 to permit the various components in the SoC 100 to communicate with each other. For example, in one physical implementation, the DPE array 105 may be disposed in an upper right portion of the integrated circuit forming the SoC 100. However, using the NoC 120, the array 105 can nonetheless communicate with, for example, programmable logic (PL) 125, a processor subsystem (PS) 130 or input/output (I/O) 135 which may be disposed at different locations throughout the SoC 100.

In addition to providing an interface between the DPEs 110 and the NoC 120, the SoC interface block 115 may also provide a connection directly to a communication fabric in the PL 125. In this example, the PL 125 and the DPEs 110 form a heterogeneous processing system since some of the kernels in a dataflow graph may be assigned to the DPEs 110 for execution while others are assigned to the PL 125. While FIG. 1 illustrates a heterogeneous processing system in a SoC, in other examples, the heterogeneous processing system can include multiple devices or chips. For example, the heterogeneous processing system could include two FPGAs or other specialized accelerator chips that are either the same type or different types. Further, the heterogeneous processing system could include two communicatively coupled SoCs.

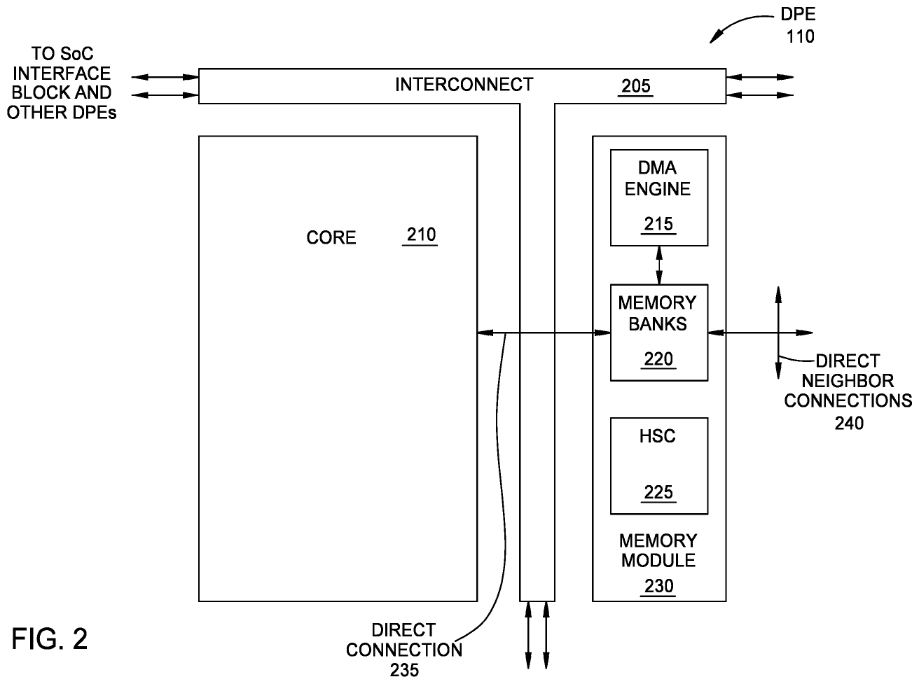

This can be difficult for a programmer to manage since communicating between kernels disposed in heterogeneous or different processing cores can include using the various communication interfaces shown in FIG. 1 such as the NoC 120, the SoC interface block 115, as well as the communication links between the DPEs 110 in the array 105 (which are shown in FIG. 2).

In one embodiment, the SoC interface block 115 includes separate hardware components for communicatively coupling the DPEs 110 to the NoC 120 and to the PL 125 that is disposed near the array 105 in the SoC 100. In one embodiment, the SoC interface block 115 can stream data directly to a fabric for the PL 125. For example, the PL 125 may include an FPGA fabric which the SoC interface block 115 can stream data into, and receive data from, without using the NoC 120. That is, the circuit switching and packet switching described herein can be used to communicatively couple the DPEs 110 to the SoC interface block 115 and also to the other hardware blocks in the SoC 100. In another example, SoC interface block 115 may be implemented in a different die than the DPEs 110. In yet another example, DPE array 105 and at least one subsystem may be implemented in a same die while other subsystems and/or other DPE arrays are implemented in other dies. Moreover, the streaming interconnect and routing described herein with respect to the DPEs 110 in the DPE array 105 can also apply to data routed through the SoC interface block 115.

Although FIG. 1 illustrates one block of PL 125, the SoC 100 may include multiple blocks of PL 125 (also referred to as configuration logic blocks) that can be disposed at different locations in the SoC 100. For example, the SoC 100 may include hardware elements that form a field programmable gate array (FPGA). However, in other embodiments, the SoC 100 may not include any PL 125—e.g., the SoC 100 is an ASIC.

FIG. 2 is a block diagram of a DPE 110 in the DPE array 105 illustrated in FIG. 1, according to an example. The DPE 110 includes an interconnect 205, a core 210, and a memory module 230. The interconnect 205 permits data to be transferred from the core 210 and the memory module 230 to different cores in the array 105. That is, the interconnect 205 in each of the DPEs 110 may be connected to each other so that data can be transferred north and south (e.g., up and down) as well as east and west (e.g., right and left) in the array of DPEs 110.

Referring back to FIG. 1, in one embodiment, the DPEs 110 in the upper row of the array 105 relies on the interconnects 205 in the DPEs 110 in the lower row to communicate with the SoC interface block 115. For example, to transmit data to the SoC interface block 115, a core 210 in a DPE 110 in the upper row transmits data to its interconnect 205 which is in turn communicatively coupled to the interconnect 205 in the DPE 110 in the lower row. The interconnect 205 in the lower row is connected to the SoC interface block 115. The process may be reversed where data intended for a DPE 110 in the upper row is first transmitted from the SoC interface block 115 to the interconnect 205 in the lower row and then to the interconnect 205 in the upper row that is the target DPE 110. In this manner. DPEs 110 in the upper rows may rely on the interconnects 205 in the DPEs 110 in the lower rows to transmit data to and receive data from the SoC interface block 115.

In one embodiment, the interconnect 205 includes a configurable switching network that permits the user to determine how data is routed through the interconnect 205. In one embodiment, unlike in a packet routing network, the interconnect 205 may form streaming point-to-point connections. That is, the streaming connections and streaming interconnects (not shown in FIG. 2) in the interconnect 205 may form routes from the core 210 and the memory module 230 to the neighboring DPEs 110 or the SoC interface block 115. Once configured, the core 210 and the memory module 230 can transmit and receive streaming data along those routes. In one embodiment, the interconnect 205 is configured using the Advanced Extensible Interface (AXI) 4 Streaming protocol.

In addition to forming a streaming network, the interconnect 205 may include a separate network for programming or configuring the hardware elements in the DPE 110. Although not shown, the interconnect 205 may include a memory mapped interconnect which includes different connections and switch elements used to set values of configuration registers in the DPE 110 that alter or set functions of the streaming network, the core 210, and the memory module 230.

In one embodiment, streaming interconnects (or network) in the interconnect 205 support two different modes of operation referred to herein as circuit switching and packet switching. In one embodiment, both of these modes are part of, or compatible with, the same streaming protocol—e.g., an AXI Streaming protocol. Circuit switching relies on reserved point-to-point communication paths between a source DPE 110 to one or more destination DPEs 110. In one embodiment, the point-to-point communication path used when performing circuit switching in the interconnect 205 is not shared with other streams (regardless whether those streams are circuit switched or packet switched). However, when transmitting streaming data between two or more DPEs 110 using packet-switching, the same physical wires can be shared with other logical streams.

The core 210 may include hardware elements for processing digital signals. For example, the core 210 may be used to process signals related to wireless communication, radar, vector operations, machine learning applications, and the like. As such, the core 210 may include program memories, an instruction fetch/decode unit, fixed-point vector units, floating-point vector units, arithmetic logic units (ALUs), multiply accumulators (MAC), and the like. However, as mentioned above, this disclosure is not limited to DPEs 110. The hardware elements in the core 210 may change depending on the engine type. That is, the cores in a digital signal processing engine, cryptographic engine, or FEC may be different.

The memory module 230 includes a DMA engine 215, memory banks 220, and hardware synchronization circuitry (HSC) 225 or other type of hardware synchronization block. In one embodiment, the DMA engine 215 enables data to be received by, and transmitted to, the interconnect 205. That is, the DMA engine 215 may be used to perform DMA reads and write to the memory banks 220 using data received via the interconnect 205 from the SoC interface block or other DPEs 110 in the array.

The memory banks 220 can include any number of physical memory elements (e.g., SRAM). For example, the memory module 230 may be include 4, 8, 16, 32, etc. different memory banks 220. In this embodiment, the core 210 has a direct connection 235 to the memory banks 220. Stated differently, the core 210 can write data to, or read data from, the memory banks 220 without using the interconnect 205. That is, the direct connection 235 may be separate from the interconnect 205. In one embodiment, one or more wires in the direct connection 235 communicatively couple the core 210 to a memory interface in the memory module 230 which is in turn coupled to the memory banks 220.

In one embodiment, the memory module 230 also has direct connections 240 to cores in neighboring DPEs 110. Put differently, a neighboring DPE in the array can read data from, or write data into, the memory banks 220 using the direct neighbor connections 240 without relying on their interconnects or the interconnect 205 shown in FIG. 2. The HSC 225 can be used to govern or protect access to the memory banks 220. In one embodiment, before the core 210 or a core in a neighboring DPE can read data from, or write data into, the memory banks 220, the core (or the DMA engine 215) requests a lock acquire to the HSC 225 when it wants to read or write to the memory banks 220 (i.e., when the core/DMA engine want to “own” a buffer, which is an assigned portion of the memory banks 220. If the core or DMA engine does not acquire the lock, the HSC 225 will stall (e.g., stop) the core or DMA engine from accessing the memory banks 220. When the core or DMA engine is done with the buffer, they release the lock to the HSC 225. In one embodiment, the HSC 225 synchronizes the DMA engine 215 and core 210 in the same DPE 110 (i.e., memory banks 220 in one DPE 110 are shared between the DMA engine 215 and the core 210). Once the write is complete, the core (or the DMA engine 215) can release the lock which permits cores in neighboring DPEs to read the data.

Because the core 210 and the cores in neighboring DPEs 110 can directly access the memory module 230, the memory banks 220 can be considered as shared memory between the DPEs 110. That is, the neighboring DPEs can directly access the memory banks 220 in a similar way as the core 210 that is in the same DPE 110 as the memory banks 220. Thus, if the core 210 wants to transmit data to a core in a neighboring DPE, the core 210 can write the data into the memory bank 220. The neighboring DPE can then retrieve the data from the memory bank 220 and begin processing the data. In this manner, the cores in neighboring DPEs 110 can transfer data using the HSC 225 while avoiding the extra latency introduced when using the interconnects 205. In contrast, if the core 210 wants to transfer data to a non-neighboring DPE in the array (i.e., a DPE without a direct connection 240 to the memory module 230), the core 210 uses the interconnects 205 to route the data to the memory module of the target DPE which may take longer to complete because of the added latency of using the interconnect 205 and because the data is copied into the memory module of the target DPE rather than being read from a shared memory module.

In addition to sharing the memory modules 230, the core 210 can have a direct connection to cores 210 in neighboring DPEs 110 using a core-to-core communication link (not shown). That is, instead of using either a shared memory module 230 or the interconnect 205, the core 210 can transmit data to another core in the array directly without storing the data in a memory module 230 or using the interconnect 205 (which can have buffers or other queues). For example, communicating using the core-to-core communication links may use less latency (or have high bandwidth) than transmitting data using the interconnect 205 or shared memory (which requires a core to write the data and then another core to read the data) which can offer more cost effective communication. In one embodiment, the core-to-core communication links can transmit data between two cores 210 in one clock cycle. In one embodiment, the data is transmitted between the cores on the link without being stored in any memory elements external to the cores 210. In one embodiment, the core 210 can transmit a data word or vector to a neighboring core using the links every clock cycle, but this is not a requirement.

In one embodiment, the communication links are streaming data links which permit the core 210 to stream data to a neighboring core. Further, the core 210 can include any number of communication links which can extend to different cores in the array. In this example, the DPE 110 has respective core-to-core communication links to cores located in DPEs in the array that are to the right and left (east and west) and up and down (north or south) of the core 210. However, in other embodiments, the core 210 in the DPE 110 illustrated in FIG. 2 may also have core-to-core communication links to cores disposed at a diagonal from the core 210. Further, if the core 210 is disposed at a bottom periphery or edge of the array, the core may have core-to-core communication links to only the cores to the left, right, and bottom of the core 210.

However, using shared memory in the memory module 230 or the core-to-core communication links may be available if the destination of the data generated by the core 210 is a neighboring core or DPE. For example, if the data is destined for a non-neighboring DPE (i.e., any DPE that DPE 110 does not have a direct neighboring connection 240 or a core-to-core communication link), the core 210 uses the interconnects 205 in the DPEs to route the data to the appropriate destination. As mentioned above, the interconnects 205 in the DPEs 110 may be configured when the SoC is being booted up to establish point-to-point streaming connections to non-neighboring DPEs to which the core 210 will transmit data during operation.

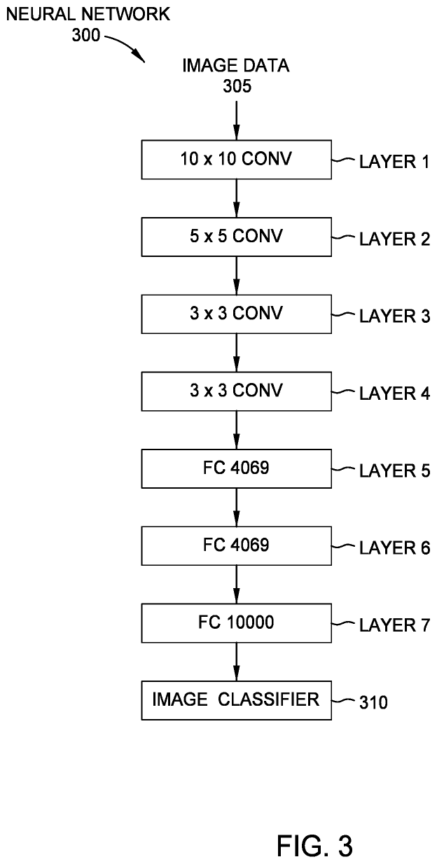

FIG. 3 illustrates a multi-layer neural network, according to an example. As used herein, a neural network 300 is a computational module used in machine learning and is based on a large collection of connected units called artificial neurons where connections between the neurons carry an activation signal of varying strength. The neural network 300 can be trained from examples rather than being explicitly programmed. In one embodiment, the neurons in the neural network 300 are connected in layers—e.g., Layers 1, 2, 3, etc. —where data travels from the first layer—e.g., Layer 1—to the last layer—e.g., Layer 7. Although seven layers are shown in FIG. 3, the neural network 300 can include hundreds or thousands of different layers.

Neural networks can perform any number of tasks such as computer vision, feature detection, speech recognition, and the like. In FIG. 3, the neural network 300 detects features in a digital image such as classifying the objects in the image, performing facial recognition, identifying text, etc. To do so, image data 305 is fed into the first layer in the neural network which performs a corresponding function, in this example, a 10×10 convolution on the image data 305. The results of that function is then passed to the next layer—e.g., Layer 2— which performs its function before passing the processed image data to the next level, and so forth. After being processed by the layers, the data is received at an image classifier 310 which can detect features in the image data.

The layers are defined in a sequential order such that Layer 1 is performed before Layer 2, Layer 2 is performed before Layer 3, and so forth. Thus, there exists a data dependency between the lower layers and the upper layer(s). Although Layer 2 waits to receive data from Layer 1, in one embodiment, the neural network 300 can be parallelized such that each layer can operate concurrently. That is, during each dock cycle, the layers can receive new data and output processed data. For example, during each dock cycle, new image data 305 can be provided to Layer 1. For simplicity, assume that during each clock cycle a part of new image is provided to Layer 1 and each layer can output processed data for image data that was received in the previous dock cycle. If the layers are implemented in hardware to form a parallelized pipeline, after seven dock cycles, each of the layers operates concurrently to process the part of image data. The “part of image data” can be an entire image, a set of pixels of one image, a batch of images, or any amount of data that each layer can process concurrently. Thus, implementing the layers in hardware to form a parallel pipeline can vastly increase the throughput of the neural network when compared to operating the layers one at a time. The timing benefits of scheduling the layers in a massively parallel hardware system improve further as the number of layers in the neural network 300 increases.

The different convolution layers 1-4 may request the underlying hardware perform different sized matrix multiplications, and correspondingly, different size dot products. Using the embodiments described below, the multiplier arrays (e.g., systolic arrays) in the cores of the hardware system executing the neural network 300 (e.g., the SoC 100 in FIG. 1) can be adapted into different configurations to improve their efficient. Further, while the embodiments herein use machine learning applications such as the layers in a neural network as an example, the adaptive multiplier arrays herein can be used with any application where hardware is requested to perform different dot products and different matrix multiplications which is not limited to only machine learning, and can include RF applications, wireless network optimizations, simulators, and the like.

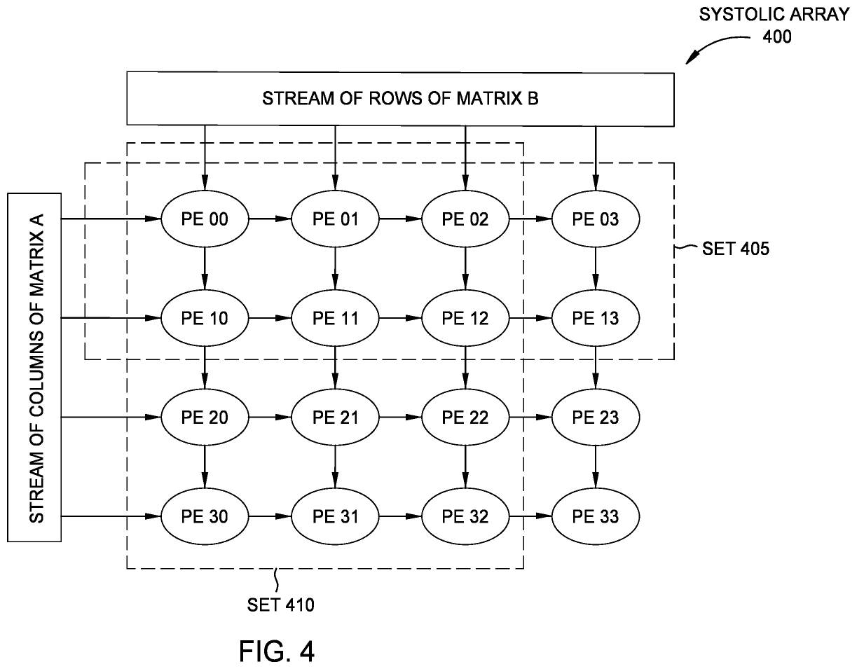

FIG. 4 illustrates a systolic array 400 for performing dot products for a neural network, according to an example. FIG. 4 is a logical view illustrating the functionality of a systolic array 400 and is not intended to illustrate the specific hardware. The systolic array 400 can be implemented using any number of different hardware circuits.

In this embodiment, the systolic array 400 is designed as a convolution block to perform convolutions. In FIG. 4, the two dimensional systolic array 400 includes a plurality of PEs (e.g., multiplication circuits) that are interconnected to form a 4×4 matrix. In this example, the four top PEs i.e., PEs 00, 01, 02, and 03—receive data from a B operand matrix while the four leftmost PEs—i.e., PEs 00, 10, 20, and 30—receive data from an A operand matrix. A scheduler in the core containing the hardware forming the systolic array 400 generates synchronization signals which synch the PEs so that each individual PEs performs its function concurrently with the others.

Because the size of the systolic array is fixed in hardware, it can perform only one type of mathematical operation (e.g., a fixed dot product). But if the systolic array is asked to execute a different type of mathematical operation on the received data, it may only use a portion of the hardware (PEs) in the array 400. This is illustrated by the sets 405 and 410 which show only a portion of the PEs being used while the others are not used to execute the corresponding dot products or matrix multiplications. Thus, without adapting the systolic array 400 into a different configuration, the underlying hardware may be inefficiently used. However, if the systolic array 400 is adaptable, the systolic array can be changed logically to a different configuration to more efficiently use the underlying hardware.

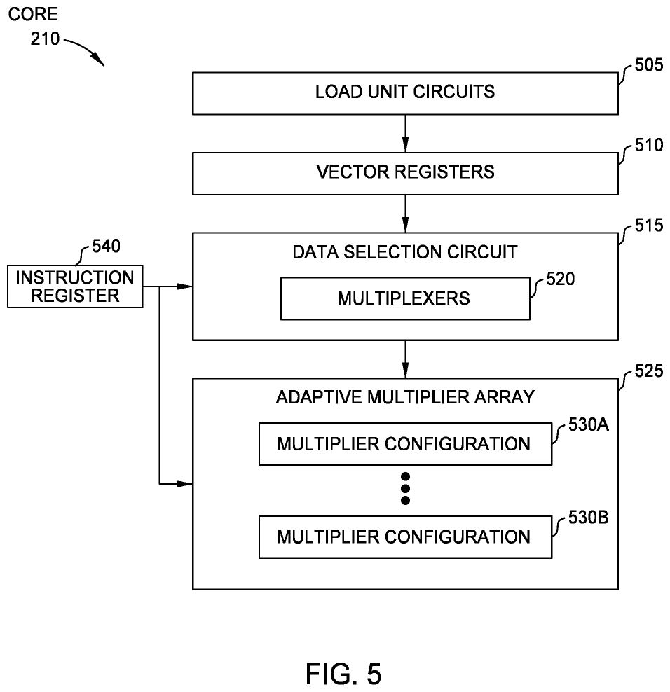

FIG. 5 is a block diagram of core 210 containing an adaptive multiplier array, according to an example. In one embodiment, the core 210 is part of the DPEs discuss in FIGS. 1 and 2, however, the adaptive multiplier array can be used in any processor or data processing engine with a core, which can include SoCs, central processing units (CPUs), ASICs, and the like.

In this example, the core 210 includes load unit circuits 505 connected to vector registers 510. The load unit circuits 505 can receive the data to be processed by the application (e.g., a ML or RF application) such as image data, audio data, weights, activations, TX/RX data, etc.

A data selection circuit 515 receives the data from the vector registers 510 and forwards this data to an adaptive multiplier array 525 that comprises multiple multiplication circuits for performing, e.g., dot products or matrix multiplications. As shown, the data selection circuit 515 includes multiplexers 520 that are used to forward the data to the multiplier array 525 to support different multiplier configurations 530. That is, based on an instruction received from an instruction register 540, the multiplexers 520 can be controlled or configured to deliver data to the multiplier array 525 to enable the different multiplier configurations 530. For example, to enable the first multiplier configuration 530A, the data selection circuit 515 may use a first set of multiplexers 520 to forward data to the multiplier array 525. To enable the second multiplier configuration 530B, the data selection circuit 515 may use a second set of the multiplexers 520 to forward data to the multiplier array 525. The different sets of multiplexers 520 may forward the data in a different way so that the multiplier array 525 performs different dot products or matrix multiplications on the data. As discussed in more detail below, each multiplier configuration 530 may correspond to a different type of dot product (e.g., a 4 bit×4 bit dot product with a 32 bit output precision versus a 8 bit×4 bit dot product with a 32 bit output precision). In this manner, the same underlying hardware (e.g., the adaptive multiplier array 525) can be used to perform different types of dot products by controlling the way data is input into the array 525 using the data selection circuit 515 in response to an instruction received from the instruction register 540.

In one embodiment, the adaptive multiplier array 525 is an adaptive systolic array with multiplication circuits arranged as shown in FIG. 4. However, in other embodiments, the multiplier array 525 may have a different arrangement for executing dot products or matrix multiplications. The embodiments herein can be used with any array of multiplication circuits that can be reconfigured by controlling the data selection circuit 515 to enable different types of mathematical operations such as dot products and matrix multiplications.

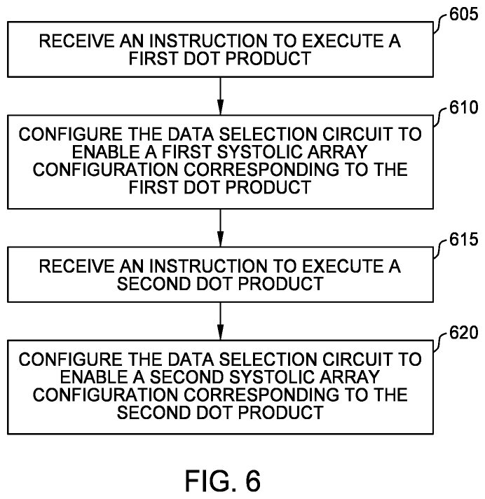

FIG. 6 is a flowchart of a method 600 for reconfiguring an adaptive multiplier array, according to an example. For ease of explanation, the method 600 is discussed in tandem with the circuitry illustrated in FIG. 5.

At block 605, the core 210 receives an instruction (which is stored in the instruction register 540) to execute a first dot product; which may be part of a matrix multiplication. Moreover, the dot product may be part of a first layer of a machine learning application, such as a neural network. However, the method 600 can be used with any type of application which instructs the hardware to perform different types of dot products or matrix multiplications.

At block 610, the core 210 configures the data selection circuit 515 to enable a first multiplier array configuration corresponding to a first dot product. That is, the data selection circuit 515 can provide data to the multiplier array such that it performs the first dot product corresponding to the first multiplier array configuration. In one embodiment, the data selection circuit 515 includes multiplexers that can be controlled to enable the various configurations of the multiplier array.

At block 615, the core 210 receives an instruction (which is stored in the instruction register 540) to execute a second dot product that is different from the first dot product. For example, the second dot product may be used by a different layer in the neural network.

At block 620, the core 210 configures the data selection circuit 515 to enable a second multiplier array configuration corresponding to the second dot product. For example, the data selection circuit 515 may use a different set of multiplexers to provide data to the multiplier array in a different manner than at block 610. This enables a different configuration of the multiplier array that performs a different dot product. Thus, the same multiplication circuitry can be reconfigured to perform different types of dot products and matrix multiplications by altering how the data selection circuit 515 provides data to the array.

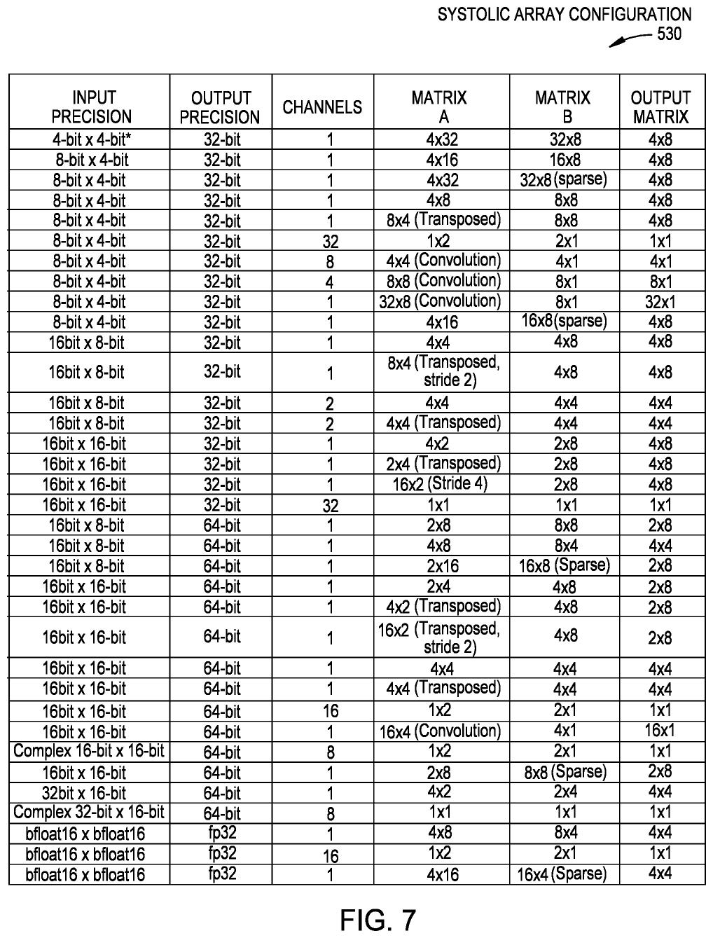

The dot products may differ according to size (number of bits of the operands), number of channels, output precision, and output matrices. FIG. 7 is a chart illustrating different multiplier array configurations 530, according to an example. That is, the row of each chart in FIG. 7 illustrates a different dot product (and different configuration 530 of the multiplier array) that can be performed using the same underlying hardware. Thus, instead of a multiplier array that can only perform a fixed dot product, the embodiments herein can enable different configurations of the multiplier array to perform different types of dot products. Doing so may result in greater throughput and higher compute efficiency.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit (IC), comprising:
a data processing engine comprising:
a data selection circuit configured to receive data, and
an adaptive multiplier array connected to the data selection circuit,
wherein the data selection circuit is configured to enable different configurations of the adaptive multiplier array, wherein each of the different configurations results in the adaptive multiplier array performing a different dot product on the received data.

2. The IC of claim 1, wherein the data selection circuit comprises multiplexers, wherein each of the different configurations corresponds to a different set of the multiplexers being used to forward data from the data selection circuit to the adaptive multiplier array.

3. The IC of claim 1, wherein the adaptive multiplier array comprises a plurality of multiplication circuits that perform the different dot products as part of matrix multiplication.

4. The IC of claim 3, wherein the plurality of multiplication circuits is arranged in a systolic array.

5. The IC of claim 1, further comprising:
a plurality of data processing engines, each comprising a copy of the data selection circuit and the adaptive multiplier array.

6. The IC of claim 5, wherein the plurality of data processing engines is arranged in an array.

7. The IC of claim 1, wherein each of the different configurations corresponds to a different layer in a neural network.

8. An IC, comprising:
a data selection circuit configured to receive data, and
an adaptive multiplier array connected to the data selection circuit, wherein the data selection circuit is configured to enable different configurations of the adaptive multiplier array, wherein each of the different configurations results in the adaptive multiplier array performing a different dot product on the received data.

9. The IC of claim 8, wherein the data selection circuit comprises multiplexers, wherein each of the different configurations corresponds to a different set of the multiplexers being used to forward data from the data selection circuit to the adaptive multiplier array.

10. The IC of claim 8, wherein the adaptive multiplier array comprises a plurality of multiplication circuits that perform the different dot products.

11. The IC of claim 10, wherein the plurality of multiplication circuits is arranged in a systolic array.

12. The IC of claim 8, further comprising:
a plurality of data processing engines, each comprising a copy of the data selection circuit and the adaptive multiplier array.

13. The IC of claim 12, wherein the plurality of data processing engines is arranged in an array.

14. The IC of claim 8, wherein each of the different configurations corresponds to a different layer in a neural network.

15. A method, comprising:
receiving, at a data processing engine, a first instruction to execute a first dot product;
configuring a data selection circuit in the data processing engine to enable a first configuration of an adaptive multiplier array corresponding to the first dot product;
receiving, at the data processing engine, a second instruction to execute a second dot product; and
configuring the data selection circuit in the data processing engine to enable a second configuration of the adaptive multiplier array corresponding to the second dot product.

16. The method of claim 15, wherein the data selection circuit comprises multiplexers, wherein the first and second configurations correspond to a different set of the multiplexers being used to forward data from the data selection circuit to the adaptive multiplier array.

17. The method of claim 15, wherein the adaptive multiplier array comprises a plurality of multiplication circuits that perform the first and second dot products.

18. The method of claim 17, wherein the plurality of multiplication circuits is arranged in a systolic array.

19. The method of claim 15, wherein the first and second dot products are performed as part of executing a neural network.

20. The method of claim 19, wherein the first dot product corresponds to a first layer of the neural network while the second dot product corresponds to a second layer of the neural network.
